(19) United States
(12) Patent Application Publication
(10) Pub. No.: US 2026/0181850 A1
(43) Pub. Date: Jun. 25, 2026

(54) SEMICONDUCTOR DEVICE WITH HYBRID CONTACT AIR SPACER CONFIGURATION

(71) Applicant: Taiwan Semiconductor Manufacturing Company, Ltd., Hsinchu (TW)

(72) Inventors: Jui-Lin Chen, Hsinchu City (TW); Yung-Ting Chang, Hsinchu City (TW); Yu-Bey Wu, Hsinchu City (TW)

(73) Assignee: Taiwan Semiconductor Manufacturing Company, Ltd., Hsinchu (TW)

(21) Appl. No.: 18/990,731

(22) Filed: Dec. 20, 2024

(51) Int. Cl. H10B 10/00

(52) U.S. Cl. CPC H10B 10/125

(57) ABSTRACT

A semiconductor circuit for a SRAM cell includes a first transistor and a second transistor on a substrate. The first transistor includes a first source contact over and coupled to a first source structure, a first drain contact over and coupled to a first drain structure, and a first gate structure laterally coupled between the first source contact and the first drain contact. The second transistor includes a second source contact over and coupled to a second source structure, a second drain contact over and coupled to a second drain structure, and a second gate structure laterally coupled between the second source contact and the second drain contact. The first drain contact is coupled to a bit line and has an air spacer on a sidewall thereof. The first source contact or the second source contact has no air spacer on a sidewall thereof.

### BACKGROUND

Semiconductor devices are used in a variety of electronic applications, such as in SRAM circuits, logic circuits, and other circuits. They are typically fabricated by sequentially depositing insulating or dielectric layers, conductive layers, and semiconductive layers over a semiconductor substrate, and patterning the various material layers using lithography to form circuit components and elements thereon. As the semiconductor industry has progressed into nanometer technology process nodes in pursuit of higher device density, higher performance, and lower power consumption, challenges from both fabrication and design issues have resulted in the development of three-dimensional designs, such as fin field effect transistors (FinFET), and gate-all-around (GAA) field effect transistors, such as nano sheet field effect transistors (NS-FETs) and nano wire field effect transistors (NW-FETs). The advantages of FinFET devices and GAA devices may include reducing the short channel effect and providing a higher current flow. Although FinFET devices and GAA devices have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a SRAM memory device in accordance with some embodiments.

FIG. 2 illustrates a circuit diagram of a SRAM memory cell of the SRAM memory device of FIG. 1 in accordance with some embodiments.

FIG. 3 illustrates a top plane view of the SRAM memory cell of FIG. 2 in accordance with some embodiments.

FIG. 4 illustrates a cross-sectional view of the SRAM memory cell of FIG. 3 taken along line A-A′ in accordance with some embodiments.

FIG. 5 illustrates a schematic view of a semiconductor device used in a SRAM memory cell and having a hybrid contact air spacer configuration in accordance with some embodiments.

FIG. 6 illustrates a cross-sectional view of a semiconductor transistor used in a logic device or system and having a hybrid contact air spacer configuration in accordance with some embodiments.

FIG. 7 illustrates a top plane view of a semiconductor transistor of FIG. 6 in accordance with some embodiments.

FIG. 8 illustrates a circuit diagram of the semiconductor transistor of FIG. 6 in accordance with some embodiments.

FIG. 9 is a pulldown Vt sigma versus metal gate CD graph comparing a traditional configuration of a SRAM circuit with a hybrid air spacer configuration of a SRAM circuit in accordance with some embodiments of the present disclosure.

FIG. 10 is a pulldown performance versus metal gate CD graph comparing a traditional configuration of a SRAM circuit, with a hybrid air spacer configuration of a SRAM circuit in accordance with some embodiments of the present disclosure, and with another configuration of a SRAM circuit in accordance with other embodiments of the present disclosure.

FIG. 11 is a Vmin versus a difference between PG Vt and PU Vt comparing a traditional configuration of a SRAM circuit with a hybrid air spacer configuration of a SRAM circuit in accordance with some embodiments of the present disclosure.

FIG. 12 is flow diagram that illustrates an example method of forming a semiconductor device in accordance with some embodiments.

FIGS. 13-20 illustrate cross-sectional views of various stages of forming a semiconductor device having a hybrid air spacer configuration in accordance with some embodiments.

FIG. 21 is a schematic view of a photomask used to define patterns for forming air spacers on sidewalls of drain contacts in a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “cupper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As the semiconductor industry has progressed into nanometer technology process nodes in pursuit of higher device density, higher performance, and lower costs, challenges from both fabrication and design issues have resulted in the development of three-dimensional designs, such as the fin field effect transistor (FinFET), and the gate-all-around (GAA) field effect transistor, such as the nanosheet field effect transistor (NS-FET). A FinFET is fabricated with a thin vertical “fin” (or fin structure) extending from a substrate. The channel of the FinFET is formed in this vertical fin. A gate is provided over the fin. A NS-FET is fabricated with a plurality of nano sheets formed over a substrate and between a source structure and a drain structure, with the gate structure wrapping around the plurality of nanosheet channels. The channels of the NS-FET are formed in these plurality of nano sheets. The advantages of a FinFET device and a NS-FET device may include reducing the short channel effect and providing a higher current flow. The FinFET transistors and the NS-FET transistors are widely used in a variety of electronic applications, such as in static random-access memory (SRAM) circuits, logic circuits, and other circuits. Although FinFET devices and the NS-FET devices have generally been adequate for their intended purpose, they have not been entirely satisfactory in all respects.

A SRAM circuit includes a plurality of contacts that play an important role for the performance of the SRAM circuit. The SRAM circuit may have a minimum operating voltage (Vmin) limitation due to a Vt sigma, which refers to a statistical variation in the threshold voltage (Vt) of transistors in an integrated circuit. The Vmin of the SRAM is often limited by the variability in threshold voltage (Vt) among transistors. High Vt sigma can lead to increased failures in memory cells at lower voltages, thus restricting Vmin is needed. In some situations, an air spacer (or an air gap) can be formed on a sidewall of a contact (e.g., a source contact or a drain contact) to advantageously reduce a parasitic capacitor, which is formed by the contact and an adjacent conductive component as well as the dielectric therebetween, due to the lowest dielectric coefficient k (almost equal to zero) of the air spacer, however, the air spacer may also disadvantageously increase resistor of the contact, thereby causing poor performance of the SRAM circuit.

A logic circuit also includes a plurality of contacts that play an important role for performance of the logic circuit. In some situations, an air spacer can be formed on a sidewall of a contact (e.g., a source contact and a drain contact) to advantageously reduce a parasitic capacitor, which is formed by the contact and an adjacent conductive component as well as one or more dielectric materials therebetween, however, the air spacer may also disadvantageously increase resistor of the contact, thereby causing poor performance of the logic circuit.

The present disclosure provides various embodiments of a semiconductor circuit implemented as a static random-access memory (SRAM) circuit. In some embodiments, the SRAM circuit includes at least a first transistor and a second transistor formed on a substrate. The first transistor includes a first source contact formed over and coupled to a first source structure, a first drain contact formed over and coupled to a first drain structure, and a first gate structure formed laterally between the first source contact and the first drain contact. The second transistor includes a second source contact formed over and coupled to a second source structure, a second drain contact formed over and coupled to a second drain structure, and a second gate structure formed laterally between the second source contact and the second drain contact. In some embodiments, the first drain contact of the first transistor is coupled to a bit line (BL) or a complementary bit line (BLB), and has a first air spacer on a sidewall thereof. In some embodiments, the second drain contact of the second transistor is not coupled to a BL or a BLB, and has no air spacer on a sidewall thereof. In some embodiments, none of the first source contact and the second source contact has any air spacer on a sidewall thereof. That it, in the SRAM circuit, in case that a drain contact of a transistor is coupled to a BL or BLB, the drain contact has an air spacer (or an air gap) on a sidewall thereof. Otherwise, in case that a drain contact of a transistor is not coupled to a BL or BLB, the drain contact has no air spacer on a sidewall thereof. In addition, each source contact of the SRAM circuit has no air spacer on a sidewall thereof. As such, in the SRAM circuit, any drain contact coupled to a BL or BLB advantageously has reduced parasitic capacitance, due to the air spacer formed on a sidewall thereof. In addition, in the SRAM circuit, none of any other drain contacts not coupled to a BL or BLB, or any source contacts, suffers an increased resistance, due to no air spacer formed on a sidewall thereof. In this way, the SRAM circuit adopting hybrid contacts (that is some contacts having air spacers on sidewalls thereof, while other contacts having no air spacers on sidewalls thereof) may achieve improved performance, such as advantageously reduced parasitic capacitance for any drain contacts coupled to BL/BLB, and advantageously improved Icell current for any source contacts and any other drain contacts not coupled to BL/BLB.

The present disclosure also provides various embodiments of a semiconductor circuit implemented as a logic circuit. In some embodiments, in a logic circuit, an air spacer is formed on a sidewall of any drain contact to advantageously reduce a capacitance of a parasitic capacitor, formed by the drain contact and an adjacent conductive component as well as the dielectric therebetween, due to the lowest dielectric coefficient k (almost equal to zero) of the air spacer. While no air spacer is formed on a sidewall of any source contact, and thus the source contact does not suffer an increased resistance of the parasitic resistor, thereof obtaining improved Icell current for the source contact.

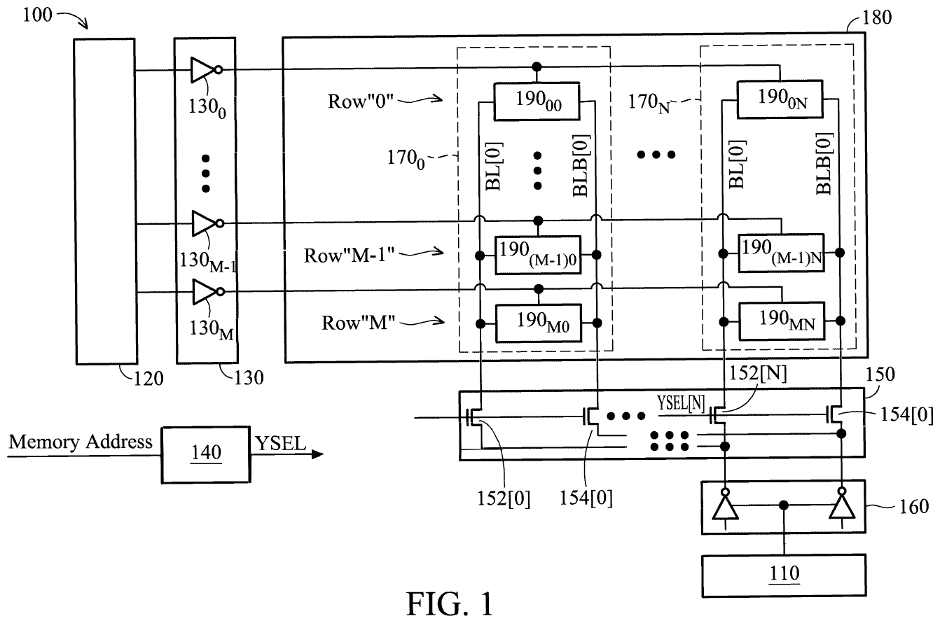

FIG. 1 illustrate a schematic view of an example SRAM device 100 with a write assist circuit 110 that includes a boost capacitor, according to various embodiments of the present disclosure. The SRAM device 100 includes a row decoder 120, a word line driver 130, a column decoder 140, a column multiplexer (MUX) 150, a write driver circuit 160, and an SRAM array 180. The SRAM array 180 includes a number of SRAM memory cells 190. The memory cells 190 can be arranged in one or more arrays in the SRAM device 100. In the illustrated example of FIG. 1, a single SRAM array 180 is shown to simplify the description of the disclosed embodiments. The SRAM array 180 has “M+1” number of rows and “N+1” number of columns. For example, the SRAM array 180 includes the memory cells 190 arranged over rows, row₀ to row_{M}, and columns 170₀ to 170_{N}. Accordingly, the notation “190₀₀” refers to one of the memory cells 190 located in row₀ and column 170₀. Similarly, the notation “190M_{N}” refers to another one of the memory cells 190 located in row_{M} and column 170_{N}.

Each of the SRAM memory cells 190 in the SRAM array 180 is accessed, e.g., for memory read and memory write operations, using a memory address. Based on a portion of the memory address, the row decoder 120 selects a row (e.g., one of the row₀ to row_{M}) of the memory cells 190 to access via the word line driver 130 (e.g., a corresponding one of a number of word line drivers 130₀ . . . 130M). Also, based on the memory address, the column decoder 140 selects a column of memory cells 170₀-170_{N} to access via the write assist circuit 110 and the column MUX 150, according to some embodiments of the present disclosure. Based on another portion of the memory address, the column decoder 140 outputs a corresponding YSEL signal to activate a corresponding pair of y-select transistors, 152 and 154, in the column MUX 150 to access a corresponding column. Each column includes a bit line pair, BL and BLB. The notation “BL” refers to a bit line, and the notation “BLB” refers to the complementary bit line. For example, to access the memory cells in the column 170₀, the column decoder 140 outputs YSEL[0] signal to active the pair of transistors 152[0] and 154[0] corresponding to the column 170₀ so as to allow access the corresponding pair of bit lines BL[0] and BLB[0]. In another example, to access the memory cells in the column 170_{N}, the column decoder 140 outputs YSEL[N] signal to active the pair of transistors 152[N] and 154[N] corresponding to the column 170_{N} so as to allow access the corresponding pair of bit lines BL[N] and BLB[N]. In some embodiments, the write driver circuit 160 generates voltages for the bit line pair of BL and BLB in the accessed one of columns 170₀ to 170_{N}. As such, the intersection of the accessed row and the accessed column of memory cells results in access to a single memory cell 190. The memory cell 190 can have any of various circuit topologies. For example, the memory cell 190 can have a “6T” circuit topology as recited later.

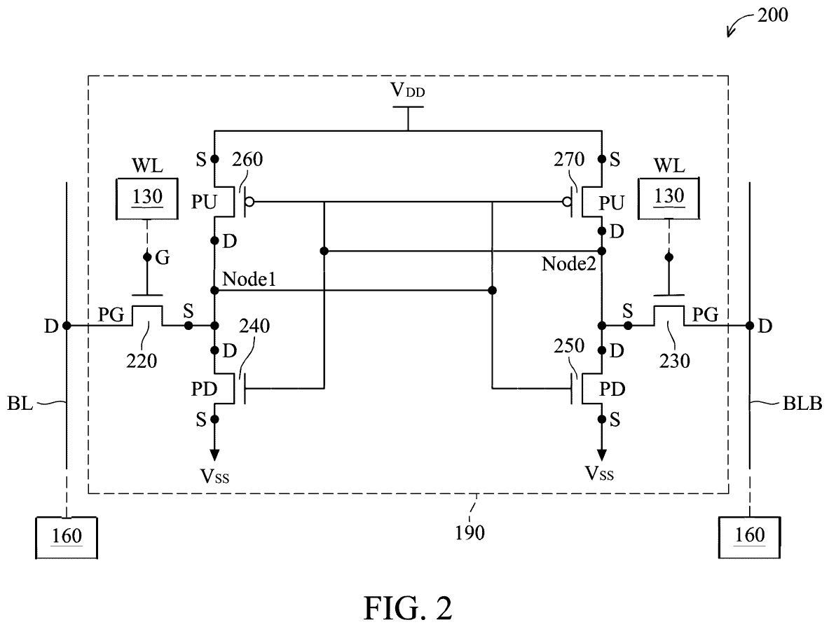

FIG. 2 illustrates a circuit diagram 200 of a SRAM memory cell 190 of the SRAM device 100 of FIG. 1 in accordance with some embodiments. In FIG. 2, an example 6T circuit topology for the memory cell 190 of the SRAM device 100 is shown. The 6T circuit topology includes n-channel metal-oxide-semiconductor (NMOS) pass devices (e.g., PG transistor 220 and PG transistor 230), NMOS pull-down devices (e.g., PD transistor 240 and PD transistor 250), and p-channel metal-oxide-semiconductor (PMOS) pull-up devices (e.g., PU transistor 260 and PU transistor 270). A voltage from the word line driver 130 controls the NMOS devices (PG transistor 220 and PG transistor 230) to pass voltages from the bit line pair of BL and BLB to a bi-stable flip-flop structure formed by the NMOS devices (PD transistor 240 and PD transistor 250) and the PMOS devices (PU transistor 260 and PU transistor 270). The bit line pair of BL and BLB voltages can be used during a memory write operation. For example, if bit line BL is at a ‘1’ or a logic high value (e.g., a power supply voltage VDD such as 0.4V, 0.6V, 0.7V, 1.0V, 1.2V, 1.8V, 2.4V, 3.3V, 5V, or any combination thereof) and complementary bit line BLB is at a ‘0’ or a logic low value (e.g., ground or 0V), the voltage applied by the word line driver 130 to the gate terminals of the NMOS pass devices (PG transistor 220 and PG transistor 230) can be at a sufficient voltage level to pass the bit line BL's logic high value and the complementary bit line BLB's logic low value to the bi-stable flip-flop structure. As a result, these logic values are written (or programmed) into the bi-stable flip-flop structure. As noted in FIG. 2, for example, drains (Ds) of the PG transistor 220 and PG transistor 230 are coupled to BL and BLB, sources of the PD transistor 240 and PD transistor 250 are coupled to V_{SS} (referring to the ground or a negative power supply voltage), and sources of the PU transistor 260 and PU transistor 270 are coupled to V_{DD} (referring to a positive power supply voltage).

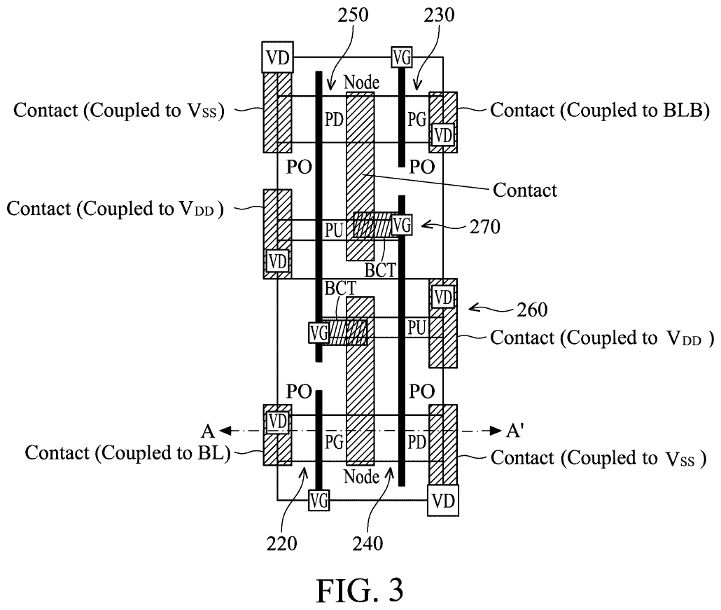

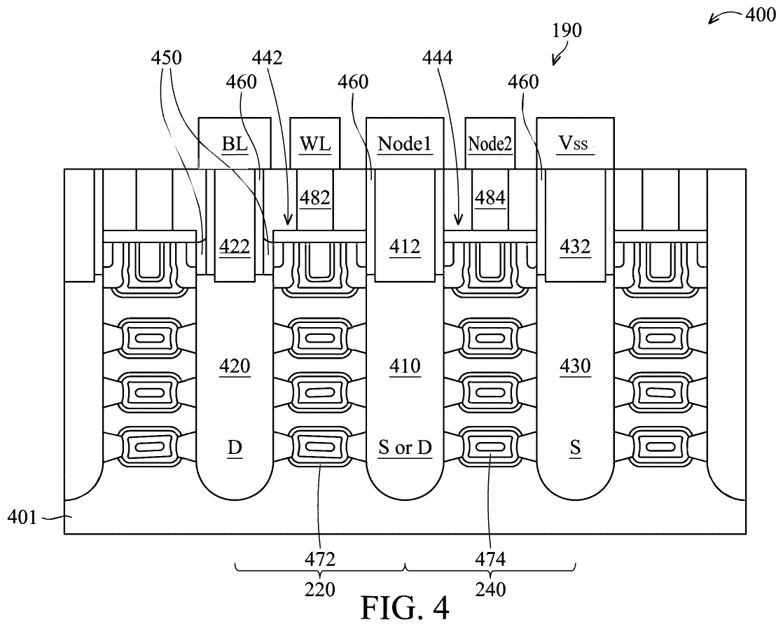

FIG. 3 illustrates a top plane view 300 of the SRAM memory cell 190 of FIG. 2 in accordance with some embodiments. FIG. 4 illustrates a cross-sectional view 400 of the memory cell 190 of the SRAM memory device of FIG. 3 taken along line A-A′ in accordance with some embodiments. In FIG. 3, POs stand for gate structures, VDs stand for via interconnect structures coupled to contacts (such as source contacts or drain contacts), VGs stand for via interconnect structures coupled to gate contacts, and BCTs stand for butted contacts (or adjacent contacts). In some embodiments, as shown in FIGS. 2, 3 and 4, a semiconductor circuit corresponding to the SRAM memory cell 190 includes a PG transistor 220 (e.g., the first transistor) and a PD transistor 240 (e.g., the second transistor) both formed on a substrate 401. In some embodiments, the first transistor 220 includes a source structure 410, a source contact 412 formed over and coupled to the source structure 410, a drain structure 420, a drain contact 422 formed over and coupled to the drain structure 420, and a gate structure 442 formed laterally between the source contact 412 and the drain contact 422. In some embodiments, the second transistor 240 includes a source structure 430, a source contact 432 formed over and coupled to the source structure 430, a drain structure 410, a drain contact 412 formed over and coupled to the drain structure 410, and a gate structure 444 formed laterally between the source contact 432 and the drain contact 412. In some embodiments, each contact of the source contacts (e.g., 412 or 432) and drain contacts (e.g., 412 or 422) has a diffusion barrier or cover layer 460, which is formed on a sidewall of the contact, and includes a material such as, for example, cobalt, ruthenium, tantalum, tantalum nitride, indium oxide, tungsten nitride, titanium nitride, or combinations thereof. In some embodiments, two transistors operatively form an inverter of a static random-access memory (SRAM) cell. Referring to FIG. 2, one PU transistor (such as the PU transistor 260) together with its corresponding PD transistor (such as the PD transistor 240) form an inverter. Another PU transistor (such as the PU transistor 270) together with its corresponding PD transistor (such as the PD transistor 250) form another inverter. The SRAM cell 190 has these two inverters cross-coupled to each other.

In some embodiments, as shown in FIG. 4, a drain contact (e.g., the drain contact 422 of the drain structure 420) is coupled to a BL (or a BLB), and has an air gap or air spacer 450 formed on a sidewall thereof. In some embodiments, the air spacer 450 is formed laterally between a sidewall of the drain contact 422 coupled to a BL/BLB and an adjacent gate structure (e.g., the gate structure 442 of the first transistor 220). In some embodiments, a drain contact 412 is coupled to a contact node (such as node Node1) (rather than coupled to a BL/BLB), and has no air spacer formed on a sidewall thereof. In some embodiments, as shown in FIG. 4, each source contact (such as the source contact 432) has no air spacer 450 formed on a sidewall thereof. In some embodiments, a source contact is coupled to one of a negative power supply voltage V_{SS}, a positive power supply voltage VDD, or a contact node (such as node Node1 or node Node2), as shown in FIG. 2. That is, any drain contact coupled to a BL/BLB has an air spacer formed on a sidewall thereof, any drain contact not coupled to a BL/BLB has no air spacer formed on a sidewall thereof, and each source contact has no air spacer formed on a sidewall thereof.

As such, in the SRAM circuit, any drain contact coupled to a BL or BLB advantageously has reduced parasitic capacitance, due to the air spacer 450 formed on a sidewall of this drain contact; while any other drain contacts not coupled to a BL or BLB, or any source contacts, do not suffer an increased resistance, due to no air spacers formed on a sidewall of those contacts. In this way, due to adopting hybrid contacts configurations (some drain contacts coupled to BL/BLB having air spacers 450, while others drain contacts and all source contacts having no air spacers), the SRAM circuit with such configurations get improved performance, such as reduced parasitic capacitance for any drain contacts coupled to BL/BLB, and improved Icell current for all source contacts and other drain contacts not coupled to BL/BLB.

In some embodiments, as shown in FIG. 4, the first transistor 220 includes a plurality of first nanosheet channels 472 formed over the substrate 401 and between the source structure 410 and the drain structure 420, the gate structure 442 wrapping around the plurality of first nanosheet channels 472. The second transistor 240 includes a plurality of second nanosheet channels 474 formed over the substrate 401 and between the source structure 410 and the drain structure 430, the gate structure 444 wrapping around the plurality of second nanosheet channels 474. Although the plurality of first nanosheet channels 472 and the plurality of second nanosheet channels 474 are implemented as channel structures of the transistor as shown in FIG. 4, other channel structures can be implemented while remaining within the scope of this disclosure. In some embodiments, the first transistor 220 (in FIG. 2) includes a first fin structure (not shown) formed over the substrate 401 and between the source structure 410 and the drain structure 420, the gate structure 442 partially wrapping around the first fin structure. The second transistor 240 (in FIG. 2) includes a second fin structure (not shown) formed over the substrate 401 and between the source structure 410 and the drain structure 430, the gate structure 444 partially wrapping around the second fin structure.

In some embodiments, as shown in FIG. 4, the first transistor 220 includes a gate contact 482 formed over and coupled to the gate structure 442 thereof, and the second transistor 240 includes a gate contact 484 formed over and coupled to the gate structure 444. In some embodiments, the gate contact 482 is coupled to a word line (WL), and the gate contact 484 is coupled to a contact node (such as node Node2), for example.

The hybrid contact air spacer configurations as shown in FIGS. 2, 3 and 4 can be applied to other memory circuit implementations. That is, in the memory circuit, any drain contacts coupled to a BL/BLB have air spacers formed on sidewalls thereof, any other drain contacts not coupled to a BL/BLB have no air spacers formed on sidewalls thereof, and any source contacts have no air spacers formed on sidewalls thereof.

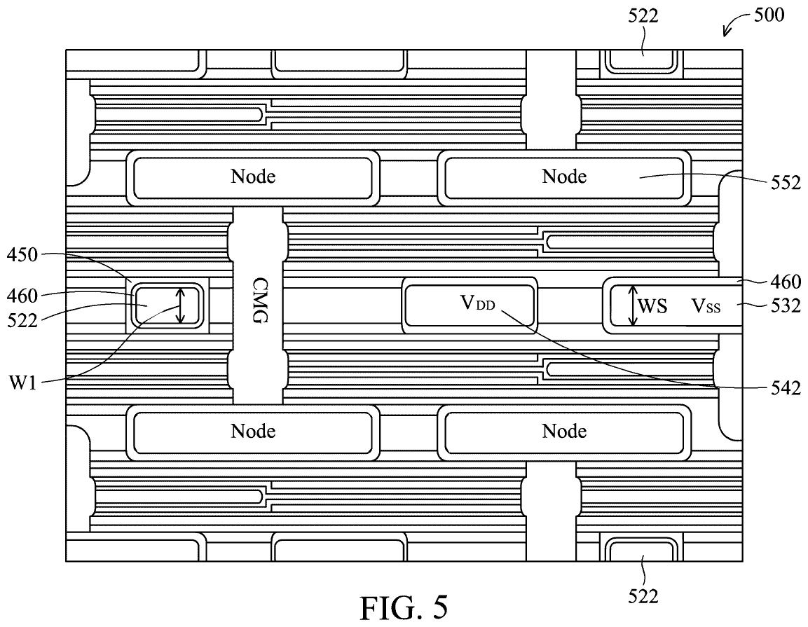

FIG. 5 illustrates a schematic view of circuit 500 of a semiconductor device (such as a SRAM memory cell 190 in FIG. 2) with a hybrid metal contact air spacer configuration in accordance with some embodiments. In some embodiments, a source contact or a drain contact includes a conductive silicide material such as Titanium Silicide (TiSi₂), Cobalt Silicide (CoSi₂), Nickel Silicide (NiSi), and Platinum Silicide (PtSi). In other embodiments, a source contact or a drain contact includes metal material such as Aluminum (Al), Copper (Cu), Tungsten (W), Cobalt (Co), and Molybdenum (Mo). The circuit 500 includes at least one drain contact 522 coupled to a BL/BLB, at least one source contact 532 coupled to V_{SS}, at least one source contact 542 coupled to VDD, and/or at least one source contact or drain contact 552 coupled to a contact node (or a node). In some embodiments, each contact (e.g., drain contact 522, source contact 532, source contact 542, or drain contact 552) has a diffusion barrier layer 460 with a material such as, for example, cobalt, ruthenium, tantalum, tantalum nitride, indium oxide, tungsten nitride, titanium nitride, or combinations thereof. In some embodiments, the drain contact 522 coupled to a BL/BLB (in FIGS. 2-4) has an air spacer 450 formed on a sidewall thereof, any other drain contacts (such as source contact 532, source contact 542, or drain contact 552) not coupled to a BL/BLB have no air spacers 450 formed on sidewalls thereof. In some embodiments, each source contact has no air spacer 450 formed on a sidewall thereof.

As such, in the SRAM circuit, any drain contact coupled to a BL or BLB advantageously has reduced parasitic capacitance, due to the air spacer 450 formed on a sidewall thereof; while any of other drain contacts not coupled to a BL or BLB, or any of the source contacts, do not suffer an increased resistance, due to no air spacers formed on a sidewall thereof. By including an air spacer coupled only to the contact of a BL/BLB, capacitance corresponding to this contact can be improved, while other contact (e.g., coupled to VDD or VSS) may not be disadvantageously impacted. In this way, due to adopting hybrid contacts configurations (some drain contacts having air spacers 450, while others drain contacts and all source contacts having no air spacers), the SRAM circuit with such configurations get improved performance, such as reduced parasitic capacitance for any drain contacts coupled to BL or BLB, and improved Icell current for all source contacts and other drain contacts not coupled to BL or BLB.

As shown in FIG. 5, in other embodiments, a width WS of a source contact (e.g., a source contact 532 coupled to a negative supply voltage V_{SS} or a source contact 542 coupled to a positive supply voltage V_{DD}) is greater than a width W1 of a drain contact 522 coupled to a BL/BLB. As such, the resistor associated with the source contact (532 or 542) coupled to a supply voltage (e.g., a negative supply voltage or a positive supply voltage) is advantageously less than the resistor of the drain contact 522 coupled to a BL/BLB. In this way, a resistance of a source contact (e.g., a source contact 532) is advantageously smaller the resistance of a drain contact 522 coupled to a BL/BLB.

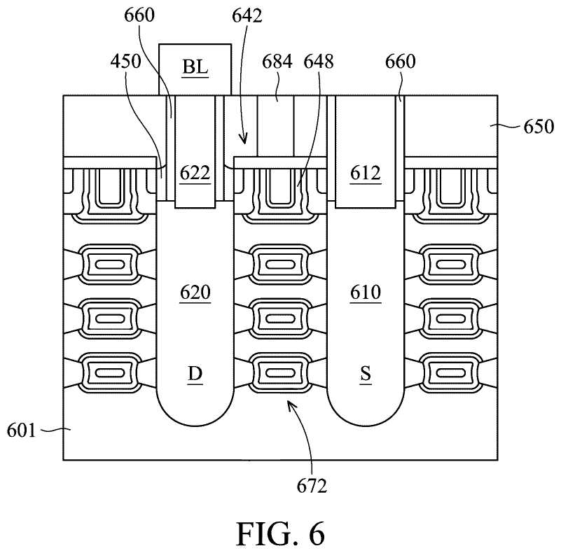

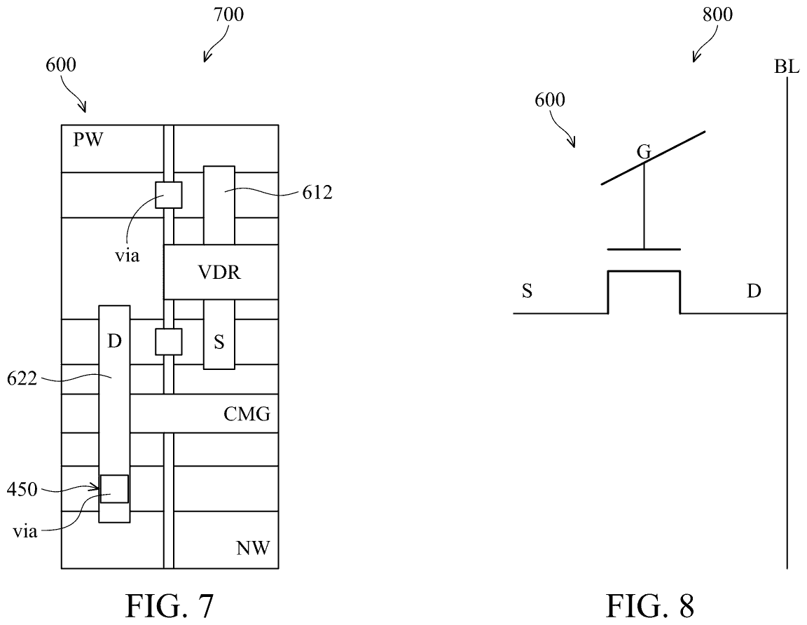

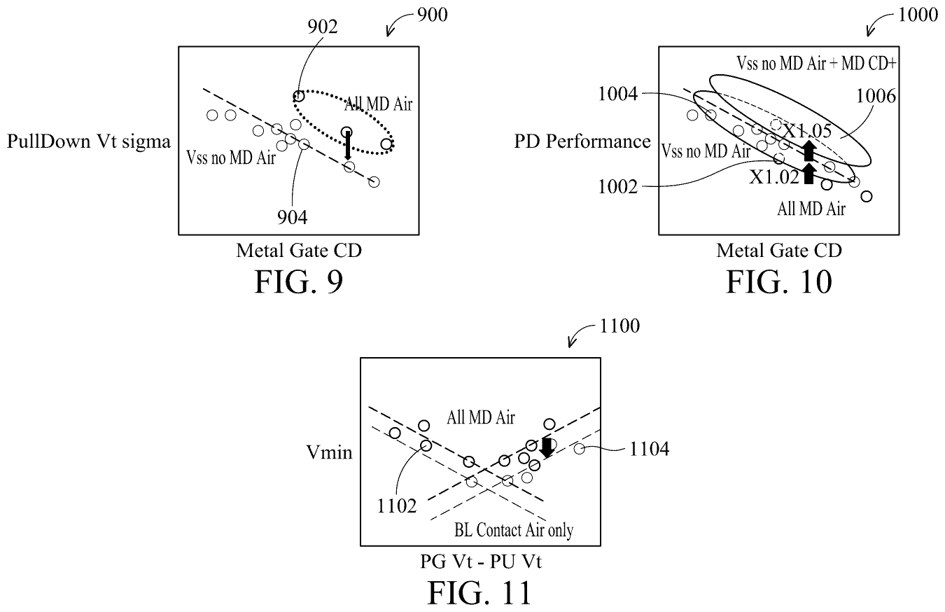

FIG. 6 illustrates a cross-sectional view of a semiconductor transistor 600 that is used in a logic device or a logic system, and has a hybrid contact air spacer configuration in accordance with some embodiments. FIG. 7 illustrates a top plane view 700 of the semiconductor transistor 600 of FIG. 6 in accordance with some embodiments. FIG. 8 illustrates a circuit diagram 800 of the semiconductor transistor 600 of FIG. 6 in accordance with some embodiments. In some embodiments, the logic device can be implemented as a ring oscillator. As shown in FIG. 8, a semiconductor transistor 600 includes a source structure S, a drain structure D, and a gate structure G, and the drain structure D is coupled to a BL.

In some embodiments, as shown in FIGS. 6 and 7, the semiconductor transistor 600 includes at least a source structure 610 formed on a substrate 601, a source contact 612 formed over and coupled to the source structure 610, a drain structure 620 formed on the substrate 601, a drain contact 622 formed over and coupled to the drain structure 620, a gate structure 642 formed laterally between the source contact 612 and the drain contact 622, and a gate contact 684 formed over and coupled to the gate structure 642. The drain contact 622 has an air spacer 450 formed on a sidewall thereof, and the source contact 612 has no air spacer 450 formed on a sidewall thereof. As such, in the logic circuit, any drain contacts coupled to a BL/BLB have air spacers 450 formed on sidewalls thereof, thereby advantageously having reduced parasitic capacitance; while any source contacts do not have air spacers 450 formed on sidewalls thereof, thereby not suffering an increased resistance. Accordingly, with such a hybrid contact air spacer configuration, performance of the logic circuit is improved.

In some embodiments, as shown in FIG. 7, the source contact 612 is coupled to a voltage dependent resistor (VDR), while the drain contact 622 is not coupled to a VDR. In some embodiments, as shown in FIG. 7, the source structure 610 is formed in a P-well (PW) region, while the drain contact 622 is formed in a N-well (NW) region. In some embodiments, as shown in FIG. 6, each source contact 612 or drain contact 622 has a diffusion barrier layer 660 with a material such as, for example, cobalt, ruthenium, tantalum, tantalum nitride, indium oxide, tungsten nitride, titanium nitride, or combinations thereof.

In some embodiments, as shown in FIG. 6, the semiconductor transistor 600 includes a channel structure 672 that includes a plurality of nanosheet channels 682 formed over the substrate 601 and between the source structure 610 and the drain structure 620, the gate structure 642 wrapping around the plurality of nanosheet channels of the channel structure 672. Although the plurality of nanosheet channels 682 are implemented as the channel structure 672 of the transistor as shown in FIG. 6, other channel structures can be implemented while remaining within the scope of this disclosure. In other embodiments, a fin (not shown) is implemented as the channel structure 672 and formed over the substrate 601 and between the source structure 610 and the drain structure 620, the gate structure 642 wrapping around the fin of the channel structure.

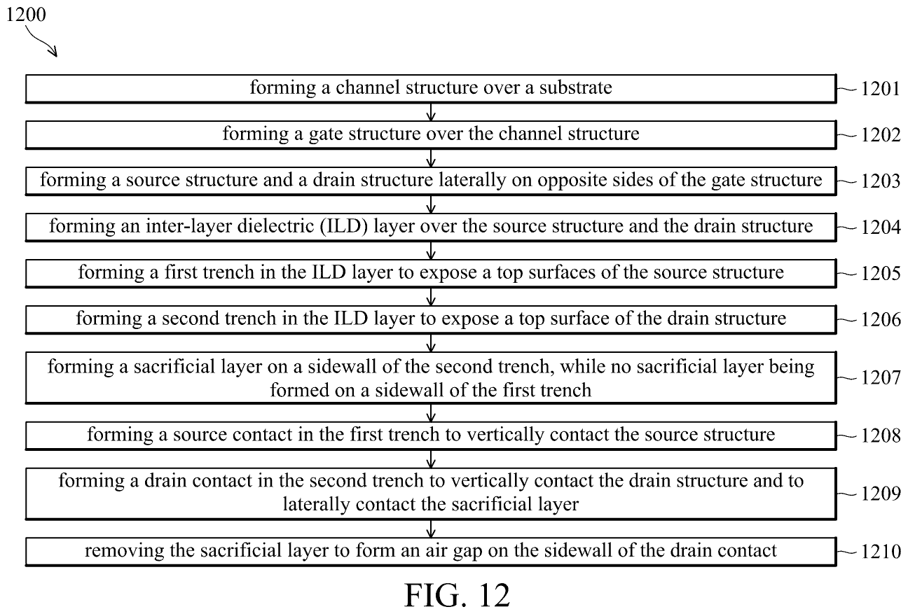

FIG. 9 is a pulldown Vt sigma versus metal gate CD graph 900 comparing a traditional configuration (trace 902) of a SRAM circuit in which all contacts have air spacers on sidewalls thereof with a hybrid air spacer configuration (trace 904) of a SRAM circuit in accordance with some embodiments oPDf the present disclosure in which only drain contacts coupled to a BL/BLB have air spacers on sidewalls thereof while any other contacts (e.g., contacts coupled to V_{SS}) have no air spacers on sidewalls thereof. As shown in FIG. 9, trace 904 achieved by the hybrid air spacer configuration of the SRAM circuit in accordance with some embodiments of the present disclosure is better than trace 902 achieved by the traditional configuration of a SRAM circuit. The pulldown Vt sigma of trace 904 can be advantageously e.g., about 89% of the pulldown Vt sigma of trace 902.

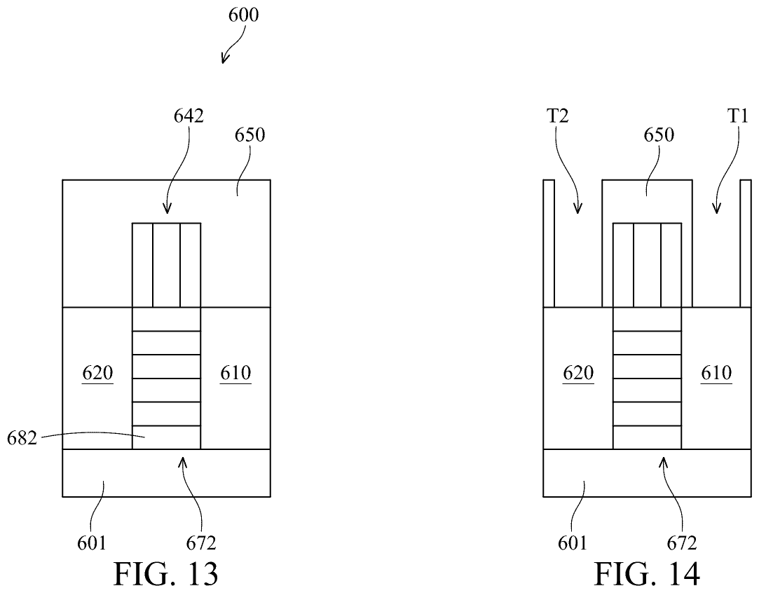

FIG. 10 is a pulldown (PD) transistor performance versus metal gate CD graph 1000 comparing a traditional configuration (trace 1002) of a SRAM circuit in which all contacts have air spacers on sidewalls thereof, with a hybrid air spacer configuration (trace 1004) of a SRAM circuit in accordance with some embodiments of the present disclosure in which only drain contacts coupled to a BL/BLB have air spacers on sidewalls thereof while any other contacts (e.g., contacts coupled to V_{SS}) have no air spacers on sidewalls thereof, and with another configuration (trace 1006) of a SRAM circuit in accordance with other embodiments of the present disclosure in which all contacts have no air spacers formed on sidewalls thereof but a size of a source contact coupled to V_{SS}/V_{DD} is larger than a size of any other contact not coupled to V_{SS}/VDD. As shown in FIG. 10, trace 1004 achieved by the hybrid air spacer configuration of the SRAM circuit in accordance with some embodiments, and another trace 1006 achieved by another configuration of the SRAM circuit in accordance with other embodiments, are better than trace 1002 achieved by the traditional configuration of a SRAM circuit according to PD transistor performance. The PD transistor performances of trace 1004 and trace 1006 can be advantageously e.g., about 1.02 or 1.05 times higher than the PD transistor performance of trace 1002, respectively.

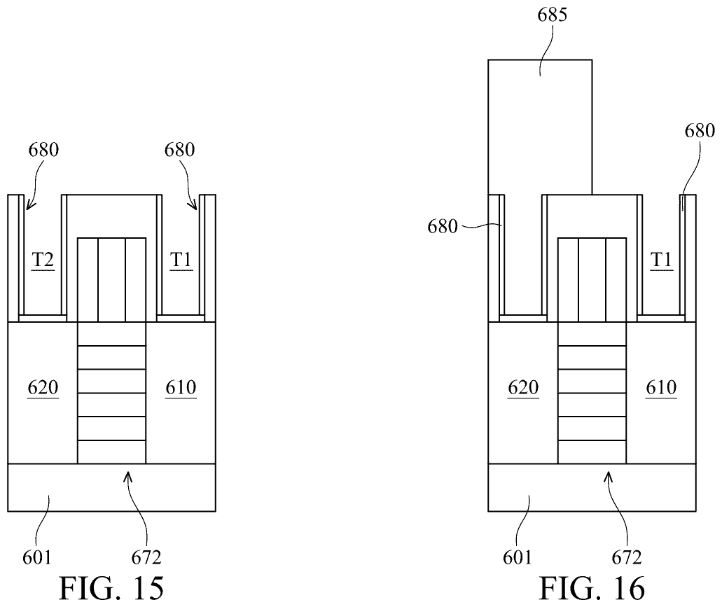

FIG. 11 is a Vmin versus a difference between PG Vt and PU Vt (PG Vt−PU Vt) graph 1100 comparing a traditional configuration (trace 1102) of a SRAM circuit in which all contacts have air spacers on sidewalls thereof with a hybrid air spacer configuration (trace 1104) of a SRAM circuit in accordance with some embodiments of the present disclosure in which only drain contacts coupled to a BL/BLB have air spacers on sidewalls thereof while any other contacts (e.g., contacts coupled to V_{SS}) have no air spacers on sidewalls thereof. As shown in FIG. 11, trace 1104 achieved by the hybrid air spacer configuration of the SRAM circuit in accordance with some embodiments of the present disclosure is better than trace 1102 achieved by the traditional configuration of a SRAM circuit.

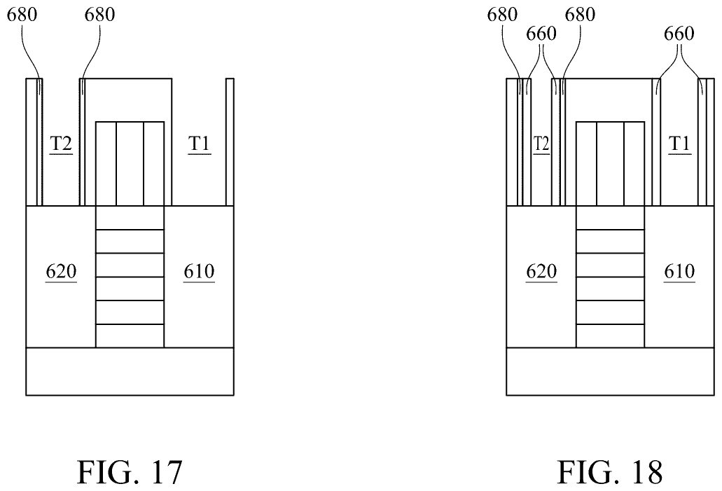

FIG. 12 is a flow diagram that illustrates an example method 1200 of forming a semiconductor transistor 600 as shown in FIGS. 6 and 7 in accordance with some embodiments. It is understood that additional operations can be provided before, during, and after processes discussed in FIG. 12, and some of the operations described below can be replaced or eliminated, for additional embodiments of the method. The order of the operations/processes may be interchangeable and at least some of the operations or processes may be performed in a different sequence. In some embodiments, at least two or more operations or processes are performed overlapping in time, or almost simultaneously.

Referring back to FIGS. 6 and 7, in some embodiments, a semiconductor transistor 600 includes at least a source structure 610 formed on a substrate 601, a source contact 612 formed over and coupled to the source structure 610, a drain structure 620 formed on the substrate 601, a drain contact 622 formed over and coupled to the drain structure 620, a gate structure 642 formed laterally between the source contact 612 and the drain contact 622, and a gate contact 684 formed over and coupled to the gate structure 642. In some embodiments, as shown in FIG. 6, each contact (e.g., source contact 612 or drain contact 622) has a diffusion barrier layer 660 with a material such as, for example, cobalt, ruthenium, tantalum, tantalum nitride, indium oxide, tungsten nitride, titanium nitride, or combinations thereof. In some embodiments, the drain contact 622 has an air spacer 450 formed on a sidewall thereof, while the source contact 612 has no air spacer formed on a sidewall thereof. As such, in the logic circuit, any drain contacts (e.g., coupled to a BL/BLB) have air spacers 450 formed on sidewalls thereof, thereby advantageously having reduced parasitic capacitance; while any source contacts do not have air spacers 450 formed on sidewalls thereof, thereby not suffering an increased resistance. Accordingly, with such a hybrid configuration of contact air spacer, performance of the logic circuit is improved.

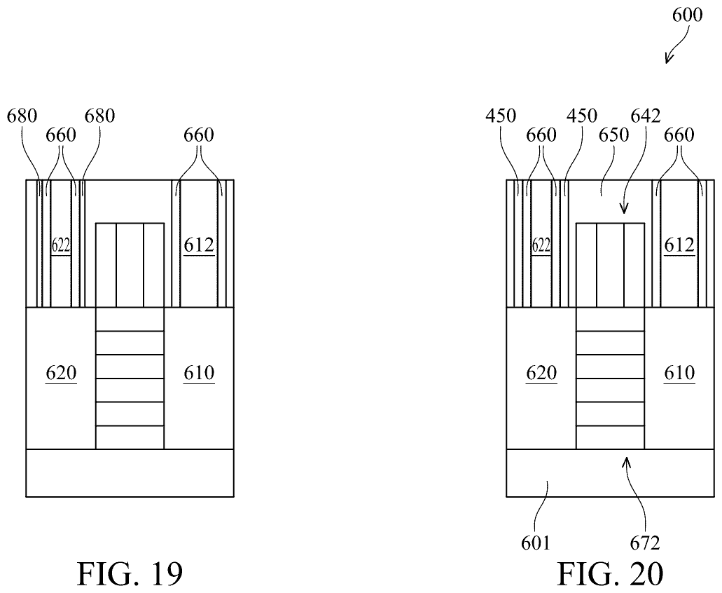

FIGS. 13-19 illustrate cross-sectional views of various stages of the method 1200 of forming a semiconductor transistor 600 including an air spacer 450 on a sidewall of a drain contact 622 in accordance with some embodiments. As shown in FIGS. 12 and 13, in some embodiments, operation 1201 includes forming a channel structure 672 over a substrate 601. As will be understood by one of ordinary skill in the art, the substrate 601 can be formed from a variety of materials including, but not limited to, bulk silicon, silicon-phosphorus (“SiP”), silicon-germanium (“SiGe”), silicon-carbide (“SiC”), germanium (“Ge”), silicon-on-insulator silicon (“SOI-Si”), silicon-on-insulator germanium (“SOI-Ge”), or combinations thereof. In some embodiments, as shown in FIG. 13, the channel structure 672 includes a plurality of nanosheet channels 682 formed over the substrate 601, and later will be laterally between the source structure 610 and the drain structure 620. Although the plurality of nanosheet channels 682 are implemented as the channel structure 672 of the semiconductor transistor 600 as shown in FIG. 13, other channel structures (such as one or more fins not shown) can be implemented as the channel structure 672 of the semiconductor transistor 600 while remaining within the scope of this disclosure.

Next, as shown in FIGS. 12 and 13, in some embodiments, operation 1202 includes forming a gate structure 642 over the channel structure 672. In some embodiments, the gate structure 642 is a metal gate structure wrapping around the plurality of nanosheet channels 682 of the channel structure 672. In some embodiments, the gate structure 642 includes a gate electrode, a gate dielectric, and a gate spacer. Next, as shown in FIGS. 12 and 13, in some embodiments, operation 1203 includes forming a source structure 610 and a drain structure 620 laterally on opposite sides of the gate structure 642. In some embodiments, an epitaxial (epi) process can be used to form the source structure 610 and the drain structure 620. In addition, the lattice constant of strained material in the source structure 610 and the drain structure 620 may be different from the lattice constant of the substrate 601. In some embodiments, the source structure 610 and the drain structure 620 include Ge, SiGe, InAs, InGaAs, InSb, GaAs, GaSb, InAlP, InP, or the like.

Next, as shown in FIGS. 12 and 13, in some embodiments, operation 1204 includes forming an inter-layer dielectric (ILD) layer 650 over the source structure 610 and the drain structure 620, as well as the gate structure 642. Prior to forming the ILD layer 650, an etch stop layer can formed over each of the source structure 610 and the drain structure 620. The etch stop layer can include silicon nitride, silicon carbide, silicon carbonitride, aluminum oxide, or combinations thereof. In some embodiments, the ILD layer 650 may include multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 650 may be formed by chemical vapor deposition (CVD), physical vapor deposition (PVD), atomic layer deposition (ALD), spin-on coating, or another applicable process.

Next, as shown in FIGS. 12 and 14, in some embodiments, operation 1205 includes forming a first trench T1 in the ILD layer 650 to expose a top surface of the source structure 610. Next, as shown in FIGS. 12 and 14, in some embodiments, operation 1206 includes forming a second trench T2 in the ILD layer 650 to expose a top surface of the drain structure 620. In some embodiments, the first trench T1 and the second trench T2 are subsequently formed one after another, and in other embodiments, the first trench T1 and the second trench T2 are concurrently formed. Various technologies such as lithography and etching can be used to form the first trench T1 and the second trench T2.

Next, as shown in FIGS. 12 and 15-17, in some embodiments, operation 1207 includes forming a sacrificial layer 680 on a sidewall of the second trench T2, while there is no sacrificial layer formed on a sidewall of the first trench T1. In some embodiments, the results of forming sacrificial layer 680 only on a sidewall of the second trench T2 but not on a sidewall of the first trench T1 can be realized by several stages, as will be briefly described below with respect to FIGS. 15, 16 and 17.

In some embodiments, at a stage as shown in FIG. 15, a sacrificial layer 680 is formed in both the first trench T1 and the second trench T2. In some embodiments, the sacrificial layer 680 includes a dielectric material having a composition different from its surrounding material layers. In some embodiments, the sacrificial layer 680 includes silicon nitride, silicon oxynitride, and/or other applicable materials. In some embodiments, the sacrificial layer 680 is formed by a deposition process, such as a chemical vapor deposition (CVD) process, physical vapor deposition (PVD) process, atomic layer deposition (ALD) process, or another application process.

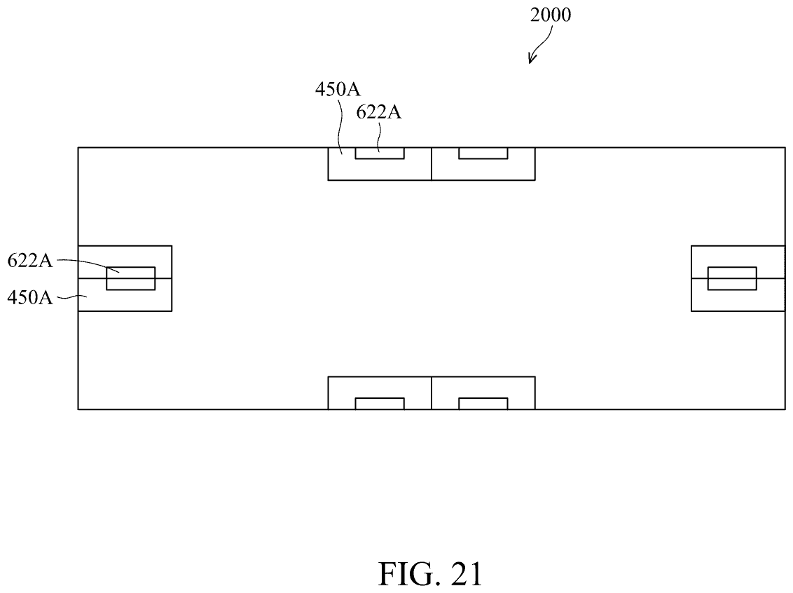

In some embodiments, at a stage as shown in FIG. 16, a photo resist layer 685 is formed to cover the second trench T2 and a portion of the ILD layer 650, while exposing the first trench T1. In the process of forming the photo resist layer 685, at least a lithography process using a photomask e.g., as shown in FIG. 21 and at least an etching process are applied. As shown in FIG. 21, patterns 622A in the photomask 2000 are used to define drain contacts 622 that will be formed later, and patterns 450A in the photomask 2000 are used to define air spacers 450 on sidewalls of the drain contacts 622 that will be formed later. As a result, as shown in FIG. 17, after the etching process as shown in FIG. 16, the sacrificial layer 680 is removed from the first trench T1, while the sacrificial layer 680 remains in the second trench T2. After that, the photo resist layer 685 is removed. In some embodiments, the bottom portion of the sacrificial layer 680 is removed in the second trench T2. In some embodiments, as shown in FIG. 18, diffusion barrier layers 660 are formed in both the first trench T1 and the second trench T2 by a deposition process, such as a chemical vapor deposition (CVD) process, physical vapor deposition (PVD) process, atomic layer deposition (ALD) process, or another application process. In some embodiments, the diffusion barrier layers 660 includes a material such as, for example, cobalt, ruthenium, tantalum, tantalum nitride, indium oxide, tungsten nitride, titanium nitride, or combinations thereof.

Next, as shown in FIGS. 12 and 19, in some embodiments, operation 1208 includes forming a source contact 612 in the first trench T1 (shown in FIG. 18) to vertically contact the source structure 610 and to laterally contact the diffusion barrier layer 660. Next, as shown in FIGS. 12 and 19, in some embodiments, operation 1209 includes forming a drain contact 622 in the second trench T2 (in FIG. 18) to vertically contact the drain structure 620 and to laterally contact the diffusion barrier layer 660. In some embodiments, the source contact 612 and the drain contact 622 are subsequently formed one after another, and in other embodiments, the source contact 612 and the drain contact 622 are concurrently formed.

Next, as shown in FIGS. 12, 19 and 20, in some embodiments, operation 1210 includes removing the sacrificial layer 680 to form an air spacer 450 on the sidewall of the drain contact 622, while no air spacer being formed on the sidewall of the source contact 612. In some embodiments, an etching process (such as a drying etching process or a wet etching process) can be used to remove the sacrificial layer 680 that is only formed on the sidewall of the drain contact 622, and thus the air spacer 450 is only formed on the sidewall of the drain contact 622. Accordingly, in the logic circuit, drain contacts 622 of the semiconductor transistor 600 have air spacers 450 therearound and are configured to couple to a BL/BLB, and source contacts 612 of the semiconductor transistor 600 have no air spacers therearound. As such, in the logic circuit, the drain contacts advantageously have reduced parasitic capacitance, while the source contacts advantageously do not suffer increased resistance. Accordingly, with such a hybrid contact air spacer configuration, performance of the logic circuit is improved.

In one aspect of the present disclosure, a semiconductor circuit is disclosed. The semiconductor circuit includes a first transistor formed on a substrate and a second transistor formed on the substrate. The first transistor includes: a first source contact formed over and coupled to a first source structure, a first drain contact formed over and coupled to a first drain structure, and a first gate structure formed laterally between the first source contact and the first drain contact. The second transistor includes: a second source contact formed over and coupled to a second source structure, a second drain contact formed over and coupled to a second drain structure, and a second gate structure formed laterally between the second source contact and the second drain contact. The first drain contact of the first transistor has a first air spacer around its sidewall, and the first source contact has no air spacer around its sidewall and the second source contact has no air spacer around its sidewall.

In another aspect of the present disclosure, a semiconductor transistor is disclosed. The semiconductor transistor includes: a source structure formed on a substrate; a source contact formed over and coupled to the source structure; a drain structure formed on the substrate; a drain contact formed over and coupled to the drain structure; a gate structure formed laterally between the source contact and the drain contact; a dielectric layer; and a first air spacer coupled between a sidewall of the drain contact and the dielectric layer, while a sidewall of the source contact is coupled to the dielectric layer with a barrier layer.

In yet another aspect of the present disclosure, a method for forming a semiconductor transistor is disclosed. The method includes: forming a channel structure over a substrate; forming a gate structure over the channel structure; forming a source structure and a drain structure laterally on opposite sides of the gate structure; forming an inter-layer dielectric (ILD) layer over the source structure and the drain structure; forming a first trench in the ILD layer to expose a top surface of the source structure; forming a second trench in the ILD layer to expose a top surface of the drain structure; forming a sacrificial layer on a sidewall of the second trench, while no sacrificial layer being formed on a sidewall of the first trench; forming a source contact in the first trench to vertically contact the source structure; forming a drain contact in the second trench to vertically contact the drain structure and to laterally contact the sacrificial layer; and removing the sacrificial layer to form an air spacer on the sidewall of the drain contact.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor circuit, comprising:
a first transistor formed on a substrate and comprising:
a first source contact formed over and coupled to a first source structure,
a first drain contact formed over and coupled to a first drain structure, and
a first gate structure extending laterally between the first source contact and the first drain contact; and
a second transistor formed on the substrate and comprising:
a second source contact formed over and coupled to a second source structure,
a second drain contact formed over and coupled to a second drain structure, and
a second gate structure extending laterally between the second source contact and the second drain contact,
wherein the first drain contact of the first transistor has a first air spacer around its sidewall, and wherein the first source contact has no air spacer around its sidewall and the second source contact has no air spacer around its sidewall.

2. The semiconductor circuit of claim 1, wherein the first drain contact of the first transistor is coupled to a bit line (BL), and wherein the second drain contact of the second transistor is coupled to a bit line bar (BLB) line, the second drain contact having a second air spacer on a sidewall thereof.

3. The semiconductor circuit of claim 1, wherein the second drain contact of the second transistor is coupled to a contact node, the second drain contact having no air spacer on a sidewall thereof.

4. The semiconductor circuit of claim 1, wherein the second drain contact of the second transistor is coupled to a contact node, the second drain contact having a third air spacer on a sidewall thereof.

5. The semiconductor circuit of claim 1, wherein the second source contact of the second transistor is coupled to a supply voltage (Vcc), the second source contact having no air spacer on a sidewall thereof, wherein a width of the second source contact of the second transistor is larger than a width of the first drain contact of the first transistor, and wherein the second source contact of the second transistor is coupled to a ground voltage (Vss), the second source contact having no air spacer on a sidewall thereof.

6. The semiconductor circuit of claim 1, wherein the first air spacer surrounds the first sidewall of the first drain contact of the first transistor which extends vertically.

7. The semiconductor circuit of claim 1, wherein the first transistor comprises a plurality of first nanosheet channels formed over the substrate and between the first source structure and the first drain structure, the first gate structure wrapping around the plurality of first nanosheet channels.

8. The semiconductor circuit of claim 1, wherein the second transistor comprises a plurality of second nanosheet channels formed over the substrate and between the second source structure and the second drain structure, the second gate structure wrapping around the plurality of second nanosheet channels.

9. The semiconductor circuit of claim 1, wherein the first transistor comprises a first fin structure formed over the substrate and between the first source structure and the first drain structure, the first gate structure partially wrapping around the first fin structure.

10. The semiconductor circuit of claim 1, wherein the second transistor comprises a second fin structure formed over the substrate and between the second source structure and the second drain structure, the second gate structure partially wrapping around the second fin structure.

11. The semiconductor circuit of claim 1, wherein the first air spacer surrounds sidewalls of the first drain contact.

12. The semiconductor circuit of claim 1, wherein the first transistor comprises a first gate contact formed over and coupled to a first gate structure, wherein the second transistor comprises a second gate contact formed over and coupled to a second gate structure, and wherein a portion of the first air spacer is laterally between the sidewall of the first drain contact and a sidewall of the first gate contact of the first transistor.

13. A semiconductor transistor, comprising:
a source structure formed on a substrate;
a source contact formed over and coupled to the source structure;
a drain structure formed on the substrate;
a drain contact formed over and coupled to the drain structure;
a gate structure formed laterally between the source contact and the drain contact;
a dielectric layer; and
a first air spacer coupled between a sidewall of the drain contact and the dielectric layer, while a sidewall of the source contact is coupled to the dielectric layer with a barrier layer.

14. The semiconductor transistor of claim 13, wherein at least the drain structure, the source structure, and the gate structure operatively form one of multiple transistors of a logic device.

15. The semiconductor transistor of claim 13, further comprising:
a plurality of nanosheet channels formed over the substrate and between the source structure and the drain structure, the gate structure partially wrapping around the plurality of nanosheet channels.

16. The semiconductor transistor of claim 13, further comprising:
a fin structure formed over the substrate and between the source structure and the drain structure, the gate structure wrapping around the fin structure.

17. The semiconductor transistor of claim 16, wherein the source contact is coupled to a first voltage dependent resistor (VDR), and wherein the drain contact is not coupled to any voltage dependent resistor (VDR).

18. A method for forming a semiconductor transistor, comprising:
forming a channel structure over a substrate;
forming a gate structure over the channel structure;
forming a source structure and a drain structure laterally on opposite sides of the gate structure;
forming an inter-layer dielectric (ILD) layer over the source structure and the drain structure;
forming a first trench in the ILD layer to expose a top surface of the source structure;
forming a second trench in the ILD layer to expose a top surface of the drain structure;
forming a sacrificial layer on a sidewall of the second trench, while no sacrificial layer being formed on a sidewall of the first trench;
forming a source contact in the first trench to vertically contact the source structure;
forming a drain contact in the second trench to vertically contact the drain structure and to laterally contact the sacrificial layer; and
removing the sacrificial layer to form an air spacer on the sidewall of the drain contact.

19. The method of claim 18, wherein the drain contact of the semiconductor transistor is configured to couple to a bit line.

20. The method of claim 19, wherein post forming the first trench and the second trench, a photomask is applied in a photolithography process to define one or more patterns for forming the sacrificial layer in the second trench.
